(19) United States
(12) Patent Application Publication
(10) Pub. No.: US 2026/0114515 A1
(43) Pub. Date: Apr. 30, 2026

(54) AEROSOL-GENERATING DEVICE INCLUDING MAGNETIC SENSOR AND METHOD OF CONTROLLING THE SAME

(71) Applicant: KT&G CORPORATION, Daejeon (KR)

(72) Inventor: Jinchul JUNG, Daejeon (KR)

(73) Assignee: KT&G CORPORATION, Daejeon (KR)

(21) Appl. No.: 19/316,127

(22) Filed: Sep. 2, 2025

(30) Foreign Application Priority Data
Oct. 25, 2024 (KR) 10-2024-0147306

(51) Int. Cl. A24F 40/51; A24F 40/53; A24F 40/57; A24F 40/60; A24F 40/65; G01R 33/02; G01R 33/09; H05B 1/02

(52) U.S. Cl. CPC A24F 40/51; A24F 40/53; A24F 40/57; A24F 40/60; A24F 40/65; G01R 33/0206; G01R 33/091; H05B 1/0252

(57) ABSTRACT

An aerosol-generating device includes a cavity, a heater configured to heat an article inserted into the cavity, a magnetic sensor disposed in the cavity, at least one processor configured to receive a detection result from the magnetic sensor and control driving of the heater, and a memory operatively connected to the at least one processor and storing executable instructions. The at least one processor is configured to, by executing the instructions stored in the memory, control the driving of the heater according to magnetic information detected by the magnetic sensor and determine whether the article is used a second time according to whether strength of a magnetic field for the magnetic information detected by the magnetic sensor is less than or equal to a reference value. Various embodiments may be possible.

### CROSS-REFERENCE TO RELATED APPLICATION

This application claims the benefit of Korean Patent Application No. 10-2024-0147306, filed on Oct. 25, 2024, in the Korean Intellectual Property Office, the entire disclosure of which is incorporated herein by reference for all purposes.

### BACKGROUND

### 1. Field of the Invention

One or more embodiments relate to an aerosol-generating device including a magnetic sensor and a method of controlling the aerosol-generating device.

### 2. Description of the Related Art

Recently, demands for alternative ways to overcome disadvantages of general cigarettes have increased. For example, there is an increasing demand for a device (e.g., a cigarette-type electronic cigarette) that generates an aerosol by electrically heating a cigarette stick. Accordingly, research is actively underway on cigarette sticks (or aerosol-generating articles) and electrically heated aerosol-generating devices into which cigarette sticks are inserted.

For example, an aerosol-generating device may generate an aerosol by atomizing an aerosol-generating material contained in an aerosol-generating article, such as a stick, a cigarette, or a cartridge.

The aerosol-generating device may obtain information about an inserted aerosol-generating article and, based on this information, control the driving of a heater or the like to generate an aerosol. For example, the aerosol-generating device may control the driving state of the heater based on information about an inserted stick, thereby providing a temperature profile appropriate for an individual stick.

The above description is information the inventor(s) acquired during the course of conceiving the present disclosure, or already possessed at the time, and was not necessarily publicly known before the present application was filed.

### SUMMARY

According to one embodiment, an aerosol-generating device and a method of controlling the aerosol-generating device are to enable the device to identify information about an inserted aerosol-generating article and control the driving of a heater or the like based on the information, even without a user directly inputting information about the inserted aerosol-generating article or a signal for driving.

Furthermore, according to one embodiment, the aerosol-generating device and the method of controlling the aerosol-generating device are to prevent a disposable aerosol-generating article from being used a second time, reused, or overused.

The technical goals obtainable from the embodiments of the present disclosure are not limited to the above-mentioned technical goals, and other unmentioned technical goals may be clearly understood from the following description by those having ordinary skill in the technical field to which the present disclosure pertains.

According to an aspect, there is provided an aerosol-generating device including a cavity, a heater configured to heat an article inserted into the cavity, a magnetic sensor disposed in the cavity, at least one processor configured to receive a detection result from the magnetic sensor and control driving of the heater, and a memory operatively connected to the at least one processor and storing executable instructions. In one embodiment, the at least one processor may be configured to, by executing the instructions stored in the memory, control the driving of the heater according to magnetic information detected by the magnetic sensor and determine whether the article is used a second time according to whether strength of a magnetic field for the magnetic information detected by the magnetic sensor is less than or equal to a reference value.

According to another aspect, there is provided an aerosol-generating system including an aerosol-generating article including magnetic printing on which magnetic information is recorded, a cavity configured to accommodate the aerosol-generating article, a heater disposed in the cavity, and a magnetic sensor configured to recognize the magnetic information of the magnetic printing. In one embodiment, when the heater is driven, the magnetic printing may be heated by the heater, so a record of the magnetic information may be weakened or erased.

According to another aspect, there is provided a method of controlling an aerosol-generating device, the method including recognizing, by a magnetic sensor, magnetic information from an article that is inserted into the aerosol-generating device and determining whether strength of a magnetic field for the magnetic information recognized by the magnetic sensor is less than or equal to a reference value. In one embodiment, when the strength of the magnetic field for the magnetic information recognized by the magnetic sensor is greater than the reference value, the method may drive a heater configured to heat the article according to the magnetic information, and when the strength of the magnetic field for the magnetic information recognized by the magnetic sensor is less than or equal to the reference value, the method may recognize that the article is used a second time.

According to one embodiment, an aerosol-generating device and a method of controlling the aerosol-generating device may identify information about an inserted aerosol-generating article through a magnetic sensor and control the driving of a heater or the like.

In addition, according to one embodiment, the aerosol-generating device and the method of controlling the aerosol-generating device may prevent a disposable aerosol-generating article from being used a second time, reused, or overused through the heater and the magnetic sensor.

Furthermore, according to one embodiment, an aerosol-generating article may easily and simply record information about the aerosol-generating article through magnetic printing.

The effects of the aerosol-generating device and the method of controlling the aerosol-generating device, according to an embodiment, are not limited to the foregoing effects, and unstated effects may be clearly understood by those skilled in the art from the description below.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a block diagram of an aerosol-generating device according to an embodiment;

FIG. 2A shows an aerosol-generating device according to an embodiment;

FIG. 2B shows an aerosol-generating device according to an embodiment;

FIG. 3A is a schematic view of an aerosol-generating device according to an embodiment;

FIG. 3B is a schematic view of the aerosol-generating device and an aerosol-generating article, according to an embodiment;

FIG. 3C is a diagram of region A of the aerosol-generating article illustrated in FIG. 3B.

FIG. 4 is a flowchart of a method of controlling an aerosol-generating device, according to an embodiment;

FIG. 5 is a flowchart of the method of controlling the aerosol-generating device according to an embodiment;

FIG. 6 is a flowchart of the method of controlling the aerosol-generating device according to an embodiment; and

FIG. 7 is a flowchart of the method of the aerosol-generating device according to an embodiment.

### DETAILED DESCRIPTION

Hereinafter, the embodiments disclosed in the present specification will be described in detail with reference to the accompanying drawings. The same or similar elements are denoted by the same reference numerals even though they are depicted in different drawings, and redundant descriptions thereof will be omitted. With regard to the description of the drawings, similar reference numerals may be used to refer to similar or related elements.

In the following description, with respect to constituent elements used in the following description, the suffixes “module” and “unit” are used only in consideration of facilitation of description, and do not have mutually distinguished meanings or functions. As used herein, the suffix “module” or “unit” may include a unit implemented in hardware, software, or firmware, and may be used interchangeably with other terms, for example, “logic,” “logic block,” “part,” or “circuitry.” A “module” or a “unit” may be a single integral component, or a minimum unit or part thereof, adapted to perform one or more functions. For example, the “module” or the “unit” may be implemented in the form of an application-specific integrated circuit (ASIC).

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and spirit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

Embodiments as set forth herein may be implemented as software including one or more instructions that are stored in a storage medium (e.g., a memory 17) that is readable by a machine (e.g., the aerosol-generating device 1). For example, a processor (e.g., the controller 12) of the machine (e.g., the aerosol-generating device 1) may invoke at least one of the one or more instructions stored in the storage medium, and may execute the same. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

In the present disclosure, the directions of the aerosol-generating device 1 may be defined based on the orthogonal coordinate system. In the orthogonal coordinate system, the x-axis direction may be defined as a leftward-rightward direction of the aerosol-generating device 1. The y-axis direction may be defined as a forward-backward direction of the aerosol-generating device 1. The z-axis direction may be defined as an upward-downward direction of the aerosol-generating device 1.

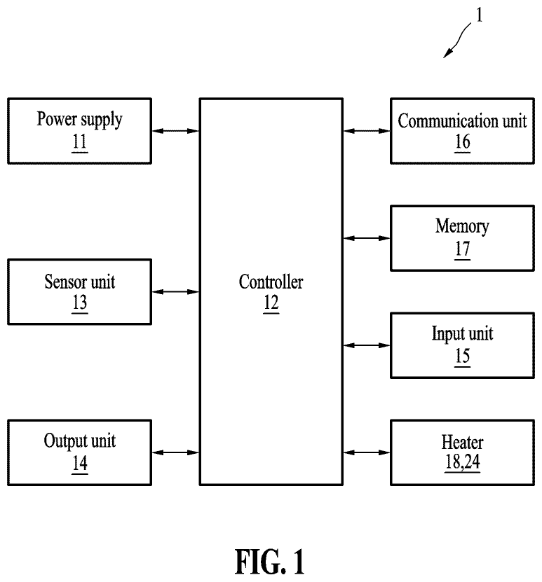

FIG. 1 is a block diagram of an aerosol-generating device according to an embodiment.

According to one embodiment, the aerosol-generating device 1 may include a power supply 11, a controller 12, a sensor unit 13, an output unit 14, an input unit 15, a communication unit 16, a memory 17, and/or a heater 18 and 24. However, the components included in the aerosol-generating device 1 are not limited to those shown in FIG. 1. That is, it will be understood by those skilled in the art related to the present embodiment that some of the components shown in FIG. 1 may be omitted or new components may be further included depending on the design of the aerosol-generating device 1.

According to one embodiment, the sensor unit 13 may detect the state of the aerosol-generating device 1 or the state of the surroundings of the aerosol-generating device 1, and may transmit the detected information to the controller 12. For example, the sensor unit 13 may include a temperature sensor, a puff sensor, an insertion detection sensor, a reuse detection sensor, an overly moist state detection sensor, a cigarette identification sensor, a cartridge detection sensor, a cap detection sensor, and/or a movement detection sensor. Meanwhile, the sensor unit 13 may further include various sensors, such as a liquid residual quantity sensor for detecting the residual quantity of liquid in the cartridge and an immersion sensor for detecting immersion of the aerosol-generating device 1.

According to one embodiment, the temperature sensor may detect a temperature to which the heater 18 and 24 is heated. The aerosol-generating device 1 may include a separate temperature sensor for detecting the temperature of the heater 18 and 24, or the heater 18 and 24 itself may serve as a temperature sensor. In an example, the temperature sensor may be used to measure impedance for the heater 18. The impedance for the heater 18 may correlate with the temperature of the heater 18. The temperature sensor may measure current and/or voltage applied to the heater 18 (or an induction coil). The impedance for the heater 18 may be obtained based on the measured current and/or voltage. The controller 12 may estimate the temperature of the heater 18 based on the obtained impedance.

In an example, the temperature sensor may include a resistance element (e.g., a thermistor), the resistance value of which varies in response to changes in the temperature of the heater 18 and 24. The temperature sensor may output a signal corresponding to the resistance value of the resistance element, and the controller 12 may determine the temperature of the heater 18 and 24 and/or a change in the temperature of the heater 18 and 24 based on the signal corresponding to the resistance value.

In another example, the temperature sensor may include a sensor that detects the resistance value of the heater 18 and 24. The temperature sensor may output a signal corresponding to the resistance value of the heater 18 and 24, and the controller 12 may determine the temperature of the heater 18 and 24 and/or a change in the temperature of the heater 18 and 24 based on the signal corresponding to the resistance value.

According to one embodiment, the temperature sensor may detect the temperature of the power supply 11. The temperature sensor may be disposed adjacent to the power supply 11. For example, the temperature sensor may be attached to one surface of the power supply 11 (e.g., a battery) and/or may be mounted on one surface of a printed circuit board. In an example, the aerosol-generating device 1 may include a power supply protection circuit module (PCM), and the temperature sensor may be disposed adjacent to the power supply 11 together with the power supply protection circuit module.

According to one embodiment, the temperature sensor may be disposed in a housing (not shown) of the aerosol-generating device 1 to detect the internal temperature of the housing (not shown).

According to one embodiment, the puff sensor may detect a user's puff.

In an example, the puff sensor may include a pressure sensor. The pressure sensor may output a signal corresponding to the internal pressure of the aerosol-generating device 1, and the controller 12 may determine the user's puff based on the signal corresponding to the internal pressure. Here, the internal pressure of the aerosol-generating device 1 may correspond to the pressure of an airflow path through which gas flows. The puff sensor may be disposed corresponding to the airflow path through which gas flows in the aerosol-generating device 1. In another example, the puff sensor may include a temperature sensor. When the user's puff occurs, temperature drop may temporarily occur in the airflow path, a space into which an aerosol-generating article is inserted (hereinafter referred to as an “insertion space”), and the heater 18 and 24. The controller 12 may determine the user's puff based on a signal corresponding to the temperature of the airflow path output from the temperature sensor.

In still another example, the puff sensor may include both a pressure sensor and a temperature sensor. In this case, the temperature sensor may measure temperature used to calibrate the internal pressure measured by the pressure sensor. In one example, the puff sensor may calibrate a signal corresponding to the internal pressure based on the temperature measured by the temperature sensor, and may output the calibrated signal. In another example, the puff sensor may output a signal corresponding to the temperature measured by the temperature sensor and a signal corresponding to the internal pressure measured by the puff sensor. In this case, the controller 12 may receive the signals, and may calibrate the signal corresponding to the internal pressure based on the signal corresponding to the temperature. In still another example, the puff sensor may include a capacitance sensor. The capacitance sensor may also be called a cap sensor or a capacitive sensor. When the user's puff occurs, a temperature change and/or aerosol flow may occur in the insertion space of the aerosol-generating article, and accordingly, a dielectric constant in the insertion space may change. The controller 12 may determine the user's puff based on a signal corresponding to the dielectric constant in the insertion space output from the capacitance sensor.

The puff sensor is not limited to the examples described above, and may be implemented as various sensors for detecting the user's puff.

According to one embodiment, the insertion detection sensor may detect insertion and/or removal of the aerosol-generating article. The insertion detection sensor may be mounted adjacent to the insertion space. In addition, the insertion detection sensor may include any combination of the examples described above.

In an example, the insertion detection sensor may include a capacitance sensor. The capacitance sensor may include at least one conductor, and the at least one conductor may be disposed adjacent to the insertion space. When the aerosol-generating article is inserted into or removed from the insertion space, capacitance around the conductor may change. The controller 12 may determine insertion and/or removal of the aerosol-generating article based on a signal corresponding to the dielectric constant in the insertion space output from the capacitance sensor.

In another example, the insertion detection sensor may include an inductive sensor. The inductive sensor may include at least one coil, and the at least one coil may be disposed adjacent to the insertion space. If the aerosol-generating article (e.g., a wrapper of the aerosol-generating article) includes a conductor, when the aerosol-generating article is inserted into or removed from the insertion space, a change in magnetic field may occur around the coil through which current flows. The controller 12 may determine insertion and/or removal of the aerosol-generating article including a conductor based on the characteristics of the current output from or detected by the inductive sensor (e.g., frequency of alternating current, a current value, a voltage value, an inductance value, and an impedance value). Alternatively, a susceptor SUS or the like may be included in the aerosol-generating article (e.g., a medium portion of the aerosol-generating article). In this case, a change in magnetic field may also occur around the coil based on insertion or removal of the susceptor or the like into or from the insertion space, and the controller 12 may determine insertion and/or removal of the aerosol-generating article based on the characteristics of the current of the inductive sensor.

The insertion detection sensor is not limited to the examples described above, and may be implemented as various sensors (e.g., a proximity sensor) for detecting insertion and/or removal of the aerosol-generating article. In addition, the insertion detection sensor may include any combination of the examples described above. According to one embodiment, the insertion detection sensor may include a switch or the like for detecting pressing by the aerosol-generating article.

According to one embodiment, the reuse detection sensor may detect whether the aerosol-generating article is being reused. In an example, the reuse detection sensor may be a color sensor for detecting the color of the aerosol-generating article. If the aerosol-generating article is used by the user, a change in the color of a portion of the wrapper may occur due to the generated aerosol or heating. The color sensor may output a signal corresponding to an optical characteristic (e.g., wavelength of light) corresponding to the color of the wrapper based on the light reflected from the wrapper. When a change in the color of a portion of the wrapper is detected, the controller 12 may determine that the aerosol-generating article inserted into the insertion space has already been used.

According to one embodiment, the overly moist state detection sensor may detect whether the aerosol-generating article is in an overly moist state. For example, the overly moist state detection sensor may include a capacitance sensor. The capacitance sensor may include at least one conductor disposed adjacent to the insertion space. The controller 12 may determine whether the aerosol-generating article is in an overly moist state based on the level of a signal corresponding to the dielectric constant or the like output from the capacitance sensor. In an example, the controller 12 may check a level range within which the level of the signal is included based on a look-up table, and may determine the moisture content of the aerosol-generating article based on the checked level range.

According to one embodiment, the cigarette identification sensor may detect whether the aerosol-generating article is authentic and/or may detect the type of the aerosol-generating article.

In an example, the cigarette identification sensor may include an optical sensor for detecting an identification material (or an identification mark) located on the outer surface (e.g., the wrapper) of the aerosol-generating article. The optical sensor may radiate light toward the identification material (or the identification mark) of the aerosol-generating article, and may detect whether the aerosol-generating article is authentic and/or may detect the type of the aerosol-generating article based on the reflected light. For example, the identification material may include a material (i.e., a luminous material) that emits light of a specific wavelength band based on the light radiated thereto. The controller 12 may determine whether the aerosol-generating article is authentic and/or may determine the type of the aerosol-generating article based on the range of the wavelength.

In another example, the cigarette identification sensor may include a capacitance sensor. The dielectric constant in the insertion space may vary depending on the type of the aerosol-generating article inserted into the insertion space. The controller 12 may determine whether the aerosol-generating article is authentic and/or may determine the type of the aerosol-generating article based on a signal corresponding to the dielectric constant or the like in the insertion space output from the capacitance sensor.

In still another example, the cigarette identification sensor may include an inductive sensor. If a conductor is included in the wrapper and/or inner portion (e.g., the medium portion) of the aerosol-generating article inserted into the insertion space, when the aerosol-generating article is inserted into the insertion space, the characteristics of the current detected by the inductive sensor (e.g., frequency of alternating current, a current value, a voltage value, an inductance value, and an impedance value) may vary depending on the type of the aerosol-generating article inserted into the insertion space. The controller 12 may determine whether the inserted aerosol-generating article is authentic and/or may determine the type of the inserted aerosol-generating article based on the characteristics of the current output from or detected by the inductive sensor.

The cigarette identification sensor is not limited to the examples described above, and may be implemented as various sensors for detecting whether the aerosol-generating article is authentic and/or detecting the type of the aerosol-generating article. In addition, the cigarette identification sensor may include any combination of the examples described above.

According to one embodiment, the cartridge detection sensor may detect mounting and/or removal of the cartridge. For example, the cartridge detection sensor may include an inductive sensor, a capacitance sensor, a resistance sensor, a Hall sensor (Hall IC), and/or an optical sensor.

According to one embodiment, the cap detection sensor may detect mounting and/or removal of the cap. For example, the cap detection sensor may include an inductive sensor, a capacitance sensor, a resistance sensor, a contact sensor, a Hall sensor (Hall IC), and/or an optical sensor. The cap may cover at least a portion of the cartridge mounted in or inserted into the aerosol-generating device 1 or may cover at least a portion of the housing of the aerosol-generating device 1. When the cap is mounted in or removed from the housing, the cap detection sensor may output a signal corresponding to mounting or removal, and the controller 12 may determine mounting or removal of the cap based on the signal corresponding to mounting or removal.

According to one embodiment, the movement detection sensor may detect movement of the aerosol-generating device 1. The movement detection sensor may be implemented as at least one of an acceleration sensor or a gyro sensor.

According to one embodiment, the sensor unit 13 may further include at least one of a humidity sensor, an air pressure sensor, a magnetic sensor, a position sensor (global positioning system (GPS)), or a proximity sensor in addition to the sensors described above. The functions of the sensors can be intuitively deduced by those skilled in the art from the names thereof, and thus detailed descriptions thereof may be omitted.

According to one embodiment, the output unit 14 may output information about the state of the aerosol-generating device 1 to provide the same to the user. The output unit 14 may include, but is not limited to, a display, a haptic unit, and/or a sound output unit. For example, information about the aerosol-generating device 1 may include a charging/discharging state of the power supply 11 of the aerosol-generating device 1, a preheating state of the heater 18 and 24, an insertion/removal state of the aerosol-generating article and/or the cartridge, a mounting/removal state of the cap, or a state in which the use of the aerosol-generating device 1 is restricted (e.g., detection of an abnormal object). The display may visually provide the information about the state of the aerosol-generating device 1 to the user. For example, the display may include a light-emitting diode (LED), a liquid crystal display panel (LCD), and an organic light-emitting diode panel (OLED). If the display includes a touchpad, the display may also be used as the input unit 15. The haptic unit may haptically provide the information about the aerosol-generating device 1 to the user. For example, the haptic unit may include a vibration motor, a piezoelectric element, and an electrical stimulation device. The sound output unit may audibly provide the information about the aerosol-generating device 1 to the user. For example, the sound output unit may convert an electrical signal into an acoustic signal and may output the acoustic signal to the outside.

According to one embodiment, the power supply 11 may supply power used for operation of the aerosol-generating device 1. The power supply 11 may include one or more batteries. The power supply 11 may supply power so that the heater 18 and 24 is heated. In addition, the power supply 11 may supply power necessary for operation of the other components included in the aerosol-generating device 1, such as the controller 12, the sensor unit 13, the output unit 14, the input unit 15, the communication unit 16, and the memory 17. The power supply 11 may be a rechargeable battery or a disposable battery. For example, the power supply 11 may be a lithium polymer (LiPoly) battery without being limited thereto. The power supply 11 may be a replaceable (separation-type) battery (hereinafter referred to as a “removable battery”). The removable battery may be mounted in a battery accommodation portion provided in the aerosol-generating device 1 or may be removed from the battery accommodation portion. The removable battery may be charged in a wired and/or wireless manner.

According to one embodiment, the heater 18 and 24 may receive power from the power supply 11 to heat the aerosol-generating article (e.g., a cigarette) and/or a medium and/or an aerosol-generating substance in the cartridge. The aerosol-generating device 1 may include a heater 18 for heating the aerosol-generating article and/or a cartridge heater 24 for heating the cartridge (i.e., a solid and/or liquid medium).

According to one embodiment, the heater 18 and 24 may be an electro-resistive heater. For example, the electro-resistive heater may include an electrically resistive material such as a metal or a metal alloy including titanium, zirconium, tantalum, platinum, nickel, cobalt, chromium, hafnium, niobium, molybdenum, tungsten, tin, gallium, manganese, iron, copper, stainless steel, and nichrome. The electro-resistive heater may be implemented as a metal wire, a metal plate having an electrically conductive track disposed thereon, or a ceramic heating element.

According to one embodiment, the heater 18 and 24 may be an induction heater. For example, the induction heater may include a susceptor that generates heat through a magnetic field. A magnetic field may be generated by an induction coil by alternating current flowing through the induction coil. The magnetic field may pass through the heater, and an eddy current may be generated in the susceptor. The susceptor may be heated based on generation of the eddy current. According to one embodiment, the susceptor may be included in the inner portion (e.g., the medium portion) of the aerosol-generating article. In this case, the susceptor included in the inner portion of the aerosol-generating article may also be heated by the induction coil.

The heater 18 and 24 is not limited to the examples described above, and may include or be replaced with various heating methods, structures, and components for heating the aerosol-generating article and/or the cartridge.

According to one embodiment, the input unit 15 may receive information input from the user. For example, the input unit 15 may include a touch panel, a button, a keypad, a dome switch, a jog wheel, and a jog switch.

According to one embodiment, the memory 17 may be hardware storing various pieces of data processed in the aerosol-generating device 1. The memory 17 may store data processed and to be processed by the controller 12. For example, the memory 17 may include at least one type of storage medium among a flash memory type memory, a hard disk type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. For example, the memory 17 may store data on an operation time of the aerosol-generating device 1, the maximum number of puffs, the current number of puffs, at least one temperature profile, and the user's smoking pattern.

According to one embodiment, the communication unit 16 may include at least one component for communication with other electronic devices (e.g., a portable electronic device). For example, the communication unit 16 may include a Bluetooth communication unit, a Bluetooth low energy (BLE) communication unit, a near-field communication unit, a wireless local area network (WLAN) communication unit, a Zigbee communication unit, an infrared data association (IrDA) communication unit, a Wi-Fi direct (WFD) communication unit, an ultra-wideband (UWB) communication unit, an Ant+ communication unit, a cellular network communication unit, an Internet communication unit, and a computer network (e.g., LAN or WAN) communication unit.

According to one embodiment, the controller 12 may control the overall operation of the aerosol-generating device 1. For example, the controller 12 may include at least one processor. The controller 12 may be implemented as an array of a plurality of logic gates or may be implemented as a combination of a general-purpose microcontroller unit (MCU) (or a microprocessor) and a memory in which a program executable by the MCU is stored. It will be understood by those skilled in the art that the controller may also be implemented as other forms of hardware.

According to one embodiment, the controller 12 may control the supply of power from the power supply 11 to the heater 18 and 24 to control the temperature of the heater 18 and 24. The controller 12 may control the temperature of the heater 18 and 24 and/or power supplied to the heater 18 and 24 based on the temperature of the heater 18 and 24 detected by the temperature sensor (e.g., the sensor unit 13). The controller 12 may control the temperature of the heater 18 and 24 and/or power supplied to the heater 18 and 24 based on the temperature profile and/or the power profile stored in the memory 17.

According to one embodiment, the controller 12 may control a power conversion circuit (not shown) electrically connected to the heater 18 and 24 and the power supply 11 to control power (e.g., voltage and/or current) supplied to the heater 18 and 24. For example, the power conversion circuit may include a DC/DC converter (e.g., a buck converter, a buck-boost converter, a boost converter, or a Zener diode) that converts power to be supplied to the heater 18 and 24 and a DC/AC converter (e.g., an inverter) that converts power to be supplied to the induction coil (not shown). The DC/AC converter may be implemented as a full-bridge circuit or a half-bridge circuit including a plurality of switching elements. For example, the power conversion circuit may include at least one switching element, such as a bipolar junction transistor (BJT) or a field effect transistor (FET).

According to one embodiment, the controller 12 may control the frequency and/or duty ratio of a current pulse input to at least one switching element of the power conversion circuit (not shown) to control the current and/or the voltage supplied to the heater 18 and 24. The duty ratio for the on/off operation of the switching element may correspond to a ratio of the voltage output from the power conversion circuit to the voltage output from the power supply 11.

According to one embodiment, the controller 12 may control power supplied to the heater 18 and 24 using at least one of a pulse width modulation (PWM) scheme or a proportional-integral-differential (PID) scheme. For example, the controller 12 may perform control using the PWM scheme such that a current pulse having a predetermined frequency and a predetermined duty ratio is supplied to the heater 18 and 24. The controller 12 may control the frequency and duty ratio of the current pulse to control power supplied to the heater 18 and 24. For example, the controller 12 may determine, based on the temperature profile, a target temperature to be controlled. The controller 12 may control power supplied to the heater 18 and 24 using the PID scheme, which is a feedback control scheme using a difference value between the temperature of the heater 18 and the target temperature, a value obtained by integrating the difference value with respect to time, and a value obtained by differentiating the difference value with respect to time.

According to one embodiment, the controller 12 may determine, based on the power profile, target power to be controlled. The controller 12 may control power supplied to the heater 18 and 24 so as to correspond to the preset target power over time.

According to one embodiment, the controller 12 may detect power supplied to the heater 18 and 24 to determine the user's puff. In more detail, the controller 12 may control power supplied to the heater 18 and 24 using the proportional-integral-differential (PID) scheme. When the user's puff occurs, temperature drop may temporarily occur in a space into which the aerosol-generating article is inserted (hereinafter referred to as an insertion space) and the heater 18 and 24. Accordingly, the power (or the current) supplied to the heater 18 and 24 may change during control of the power using the PID scheme. The controller 12 may determine the user's puff based on the change in the power controlled.

According to one embodiment, the controller 12 may prevent the heater 18 and 24 from overheating. For example, the controller 12 may control, based on the temperature of the heater 18 and 24 exceeding a preset limit temperature, operation of the power conversion circuit such that the amount of power supplied to the heater 18 and 24 is reduced or the supply of power to the heater 18 and 24 is interrupted.

According to one embodiment, the controller 12 may control charging/discharging of the power supply 11. For example, the controller 12 may check the temperature of the power supply 11 using the temperature sensor (e.g., the sensor unit 13). If the temperature of the power supply 11 is equal to or higher than a first limit temperature, the controller 12 may interrupt charging of the power supply 11. If the temperature of the power supply 11 is equal to or higher than a second limit temperature, the controller 12 may interrupt use of the power stored in the power supply 11 (e.g., discharging). The controller 12 may calculate the remaining amount of the power stored in the power supply 11. For example, the controller 12 may calculate the remaining capacity of the power supply 11 based on a voltage and/or current detection value of the power supply 11.

According to one embodiment, the controller 12 may control the supply of power to the heater 18 and 24 based on a result of the detection by the sensor unit 13.

According to one embodiment, the controller 12 may control the supply of power to the heater 18 and 24 based on insertion and/or removal of the aerosol-generating article into and/or from the insertion space. For example, upon determining that the aerosol-generating article has been inserted into the insertion space using the insertion detection sensor (e.g., the sensor unit 13), the controller 12 may perform control such that power is supplied to the heater 18 and 24. Upon determining that the aerosol-generating article has been removed from the insertion space using the insertion detection sensor (e.g., the sensor unit 13), the controller 12 may interrupt the supply of power to the heater 18 and 24. The controller 12 may determine that the aerosol-generating article has been removed from the insertion space when the temperature of the heater 18 and 24 is equal to or higher than a limit temperature or when the temperature change slope of the heater 18 and 24 is equal to or greater than a preset slope.

According to one embodiment, the controller 12 may control, based on the state of the aerosol-generating article, a power supply time and/or the amount of power supplied to the heater 18 and 24. For example, upon determining that the aerosol-generating article is in an overly moist state using the overly moist state detection sensor (e.g., the sensor unit 13), the controller 12 may increase a time during which power is supplied to the heater 18 and 24 (e.g., a preheating time).

According to one embodiment, the controller 12 may control the supply of power to the heater 18 and 24 based on whether the aerosol-generating article is being reused. For example, upon determining that the aerosol-generating article has already been used, the controller 12 may interrupt the supply of power to the heater 18 and 24.

According to one embodiment, the controller 12 may control the supply of power to the heater 18 and 24 based on whether the cartridge has been coupled and/or removed. For example, upon determining that the cartridge has been removed using the cartridge detection sensor (e.g., the sensor unit 13), the controller 12 may interrupt the supply of power to the heater 18 or 24 or may perform control such that power is not supplied to the heater 18 and 24.

According to one embodiment, the controller 12 may control the supply of power to the heater 18 and 24 based on whether the aerosol-generating substance in the cartridge has been exhausted. For example, upon determining that the temperature of the heater 18 and 24 exceeds a limit temperature during preheating of the heater 18 and 24 (i.e., in the preheating section), the controller 12 may determine that the aerosol-generating substance in the cartridge has been exhausted. Upon determining that the aerosol-generating substance in the cartridge has been exhausted, the controller 12 may interrupt the supply of power to the heater 18 and 24.

According to one embodiment, the controller 12 may control the supply of power to the heater 18 and 24 based on whether use of the cartridge is possible. For example, upon determining, based on data stored in the memory 17, that the current number of puffs is equal to or greater than the maximum number of puffs set for the cartridge, the controller 12 may determine that use of the cartridge is impossible. Alternatively, when a total time period during which the heater 18 and 24 is heated is equal to or longer than a preset maximum time period or when the total amount of power supplied to the heater 18 and 24 is equal to or greater than a preset maximum amount of power, the controller 12 may determine that use of the cartridge is impossible. In this case, the controller 12 may interrupt the supply of power to the heater 18 or 24 or may perform control such that power is not supplied to the heater 18 and 24.

According to one embodiment, the controller 12 may control the supply of power to the heater 18 and 24 based on the user's puff. For example, the controller 12 may determine whether a puff occurs and/or the intensity of a puff using the puff sensor (e.g., the sensor unit 13). When the number of puffs reaches a preset maximum number of puffs and/or when no puff is detected for a preset time period or longer, the controller 12 may interrupt the supply of power to the heater 18 and 24. When a puff is detected, the controller 12 may control the supply of power to the heater 18 and 24.

According to one embodiment, the controller 12 may control the supply of power to the heater 18 and 24 based on whether the aerosol-generating article (or the cartridge) is authentic and/or the type of the aerosol-generating article (or the cartridge). For example, the controller 12 may determine whether the aerosol-generating article is authentic and/or may determine the type of the aerosol-generating article using the cigarette identification sensor (e.g., the sensor unit 13). In an example, upon determining that the aerosol-generating article (or the cartridge) is inauthentic, the controller 12 may interrupt the supply of power to the heater 18 and 24. Upon determining that the aerosol-generating article (or the cartridge) is authentic, the controller 12 may control (e.g., commence) the supply of power to the heater 18 and 24. In another example, the controller 12 may control the supply of power to the heater 18 and 24 differently depending on the type of the aerosol-generating article (or the cartridge). In more detail, upon determining that the aerosol-generating article (or the cartridge) is a first aerosol-generating article (or a first cartridge), the controller 12 may control the temperature of the heater 18 and 24 and/or power based on a first temperature profile (or a first power profile), and upon determining that the aerosol-generating article (or the cartridge) is a second aerosol-generating article (or a second cartridge), the controller 12 may control the temperature of the heater 18 and 24 and/or power based on a second temperature profile (or a second power profile).

According to one embodiment, the controller 12 may control the output unit 14 based on a result of detection by the sensor unit 13. For example, when the number of puffs counted using the puff sensor (e.g., the sensor unit 13) reaches a preset number, the controller 12 may control the output unit 14 to visually, haptically, and/or audibly provide information that operation of the aerosol-generating device 1 will end soon. For example, the controller 12 may control the output unit 14 to visually, haptically, and/or audibly provide information about the temperature of the heater 18 and 24.

According to one embodiment, based on occurrence of a predetermined event, the controller 12 may store a history of the corresponding event in the memory 17 and may update the history. For example, the event may include events performed in the aerosol-generating device 1, such as detection of insertion of the aerosol-generating article, commencement of heating of the aerosol-generating article, detection of puff, termination of puff, detection of overheating of the heater 18 and 24, detection of application of overvoltage to the heater 18 and 24, termination of heating of the aerosol-generating article, on/off operation of the aerosol-generating device 1, commencement of charging of the power supply 11, detection of overcharging of the power supply 11, and termination of charging of the power supply 11. For example, the history of the event may include the occurrence date and time of the event and log data corresponding to the event. For example, when the predetermined event is detection of insertion of the aerosol-generating article, the log data corresponding to the event may include data on a value detected by the insertion detection sensor (e.g., the sensor unit 13). For example, when the predetermined event is detection of overheating of the heater 18 and 24, the log data corresponding to the event may include data on the temperature of the heater 18 and 24, the voltage applied to the heater 18 and 24, and the current flowing through the heater 18 and 24.

According to one embodiment, the controller 12 may control the communication unit 16 to form a communication link with an external device such as a user's mobile terminal.

According to one embodiment, upon receiving data on authentication from an external device via the communication link, the controller 12 may release restriction on use of at least one function (e.g., a heating function) of the aerosol-generating device 1. For example, the data on authentication may include the user's birthday, an identification number uniquely identifying the user, and whether authentication is completed by the user.

According to one embodiment, the controller 12 may transmit data on the state of the aerosol-generating device 1 (e.g., remaining capacity of the power supply 11 and operation mode) to the external device via the communication link. The transmitted data may be output through a display or the like of the external device.

According to one embodiment, upon receiving a request to search for the location of the aerosol-generating device 1 from the external device via the communication link, the controller 12 may control the output unit 14 to perform an operation corresponding to location search. For example, the controller 12 may perform control such that the haptic unit generates vibration or the display outputs objects corresponding to location search and termination of search.

According to one embodiment, upon receiving firmware data from the external device via the communication link, the controller 12 may perform firmware update.

According to one embodiment, the controller 12 may transmit data on a value detected by the at least one sensor unit 13 to an external server (not shown) via the communication link, and may receive, from the server, and store a learning model generated by learning the detected value through machine learning such as deep learning. The controller 12 may perform the operation of determining the user's puff pattern and the operation of generating the temperature profile using the learning model received from the server.

Although not shown in FIG. 1, the aerosol-generating device 1 may further include a power supply protection circuit. The power supply protection circuit may include at least one switching element, and may block an electric path to the power supply 11 in response to overcharging and/or overdischarging of the power supply 11. The aerosol-generating device 1 may further include a connection interface such as a universal serial bus (USB) interface, and may be connected to other external devices through the connection interface to transmit and receive information or charge the power supply 11.

The aerosol-generating article mentioned in the present disclosure may include at least one aerosol-generating rod (e.g., a medium portion) and at least one filter rod. The heater 18 may be disposed to correspond to the at least one aerosol-generating rod, and may be designed differently depending on the arrangement order and/or positions of the aerosol-generating rod and the filter rod. The aerosol-generating rod may contain at least one of nicotine, an aerosol-generating substance, and an additive. For example, the aerosol-generating substance may include glycerin (e.g., vegetable glycerin (VG)) and/or propylene glycol (PG) and may also include various other substances. For example, the additive may include a flavoring agent and/or an organic acid and may also include various other substances. For example, the aerosol-generating rod may include an aerosol-generating substrate (e.g., a sheet) impregnated with a liquid non-tobacco substance (e.g., an aerosol-generating substance and/or nicotine) and/or may contain a solid tobacco substance (e.g., leaf tobacco and reconstituted tobacco). The tobacco substance may be contained in the aerosol-generating rod in various forms, such as shredded tobacco, granules, and powder. According to one embodiment, the additive of the aerosol-generating rod may include an alkaline substance. Based on the alkaline substance, nicotine contained in the tobacco substance in the aerosol-generating rod may have an alkaline pH (e.g., pH 7.0 or higher). In this case, freebase nicotine may be released from the aerosol-generating rod even at a low temperature. According to one embodiment, the aerosol-generating rod may include two or more aerosol-generating rods, each of which may contain a tobacco substance and/or a non-tobacco substance. Meanwhile, although not shown, the at least one aerosol-generating rod and the at least one filter rod may individually and/or integrally be wrapped by at least one wrapper. In the present disclosure, the aerosol-generating article may be referred to as a stick.

The cartridge mentioned in the present disclosure may contain an aerosol-generating substance having any one state among a liquid state, a solid state, a gaseous state, and a gel state. The aerosol-generating substance may include a liquid composition. For example, the liquid composition may be a liquid containing a tobacco-containing substance including a volatile tobacco flavor component or may be a liquid containing a non-tobacco substance. Meanwhile, the cartridge may include a storage part that contains the aerosol-generating substance and/or a liquid delivery part that is impregnated with (contains) the aerosol-generating substance. For example, the liquid delivery part may include a wick formed of, e.g., cotton fiber, ceramic fiber, glass fiber, or porous ceramic. The cartridge heater 24 may be included in the cartridge in a coil-shaped structure surrounding (or wound around) the liquid delivery part or a structure contacting one side of the liquid delivery part. Alternatively, the cartridge heater 24 may be included in the aerosol-generating device 1, which is removable from the cartridge.

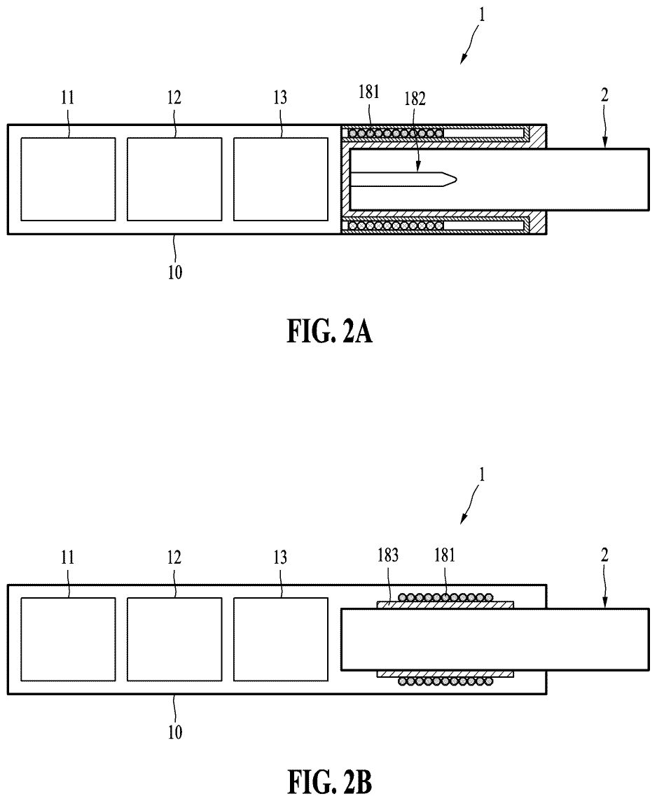

FIG. 2A shows an aerosol-generating device 1 according to an embodiment. FIG. 2B shows an aerosol-generating device 1 according to an embodiment.

According to one embodiment, the aerosol-generating device 1 may include a housing 10, a power supply 11, a controller 12, a sensor unit 13, and/or a heater 182 and 183 (e.g., the heater 18 in FIG. 1). However, it will be understood by those skilled in the art related to the present embodiment that the components included in the aerosol-generating device 1 are not limited to those shown in FIG. 2A or FIG. 2B and that some of the components may be omitted or new components may be further included. The aerosol-generating device 1 shown in FIG. 2A may be referred to as an “internal heating-type” aerosol-generating device that heats the inner side of an aerosol-generating article 2. The aerosol-generating device 1 shown in FIG. 2B may be referred to as an “external heating-type” aerosol-generating device that heats the outer side of the aerosol-generating article 2. In the drawings below, a description of configurations identical to those shown in FIG. 1 will be omitted.

According to one embodiment, the housing 10 may provide a space that is open upwardly to allow the aerosol-generating article 2 to be inserted thereinto. In the present disclosure, the space that is open upwardly may be referred to as an insertion space. The insertion space may be formed so as to be depressed in the housing 10 to a predetermined depth so that at least a portion of the aerosol-generating article 2 may be inserted thereinto. The depth of the insertion space may be equal to or greater than the length of a region of the aerosol-generating article 2 in which an aerosol-generating substance and/or a medium is contained. The lower end of the aerosol-generating article 2 may be inserted into the housing 10, and the upper end of the aerosol-generating article 2 may protrude outside the housing 10. A user may inhale an aerosol while holding the externally exposed upper end of the aerosol-generating article 2 in the mouth.

According to one embodiment, the heater 182 and 183 may heat the aerosol-generating article 2.

Referring to FIG. 2A, the heater 182 may be an internal heating-type heater.

According to one embodiment, the internal heating-type heater may be elongated upwardly in the space into which the aerosol-generating article 2 is inserted (i.e., the insertion space). For example, as shown in the drawings, the internal heating-type heater may include a rod-shaped or needle-shaped heating element. Alternatively, the internal heating-type heater may include various other heating elements, such as a tubular heating element or a plate-shaped heating element. The internal heating-type heater may be inserted through the lower portion of the aerosol-generating article 2.

According to one embodiment, the internal heating-type heater may include an electro-resistive heater and/or an induction heater.

For example, the electro-resistive heater may include an electro-resistive material, which is provided on the inner side (e.g., in the cavity or on the inner surface) or outer side (e.g., on the outer surface) thereof, and may generate heat as current flows through the electro-resistive material. In this case, the electro-resistive heater may be electrically connected to the power supply 11, and may directly generate heat using current received from the power supply 11. Meanwhile, an induction coil 181 may be omitted.

For example, in the case of an induction heater, the aerosol-generating device 1 may include an induction coil 181 surrounding at least a portion of the internal heating-type heater (e.g., disposed outside the heater so as to correspond to the length of at least a portion of the heater). In this case, a magnetic flux concentrator may be further provided outside the induction coil 181 in order to increase efficiency of induction heating. The induction heater may include a susceptor, and may generate heat based on a magnetic field generated by the induction coil 181. According to one embodiment, the induction heater (e.g., the susceptor) (or a heater module including the same) may be disposed to be removable from the housing 10. According to one embodiment, the heater 182 may be a multi-heater. The multi-heater may include a first heater and a second heater, and may be inserted into the aerosol-generating article 2. The first heater and the second heater may be disposed side by side in the longitudinal direction. The first heater and the second heater may operate as an electro-resistive heater and/or an induction heater, and may be heated sequentially or simultaneously. In this case, the first heater and the second heater may be disposed at positions corresponding to the positions of two or more aerosol-generating rods in the longitudinal direction, respectively. Alternatively, the first heater and the second heater may be disposed at positions corresponding to the positions of a first portion and a second portion of one aerosol-generating rod in the longitudinal direction, respectively. Meanwhile, if the heater 182 is an induction heater, the aerosol-generating device 1 may include a first induction coil and a second induction coil, and the first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 182 in the longitudinal direction, respectively. In addition, three or more heaters and/or three or more induction coils may be included.

According to one embodiment, the susceptor may be disposed on (or included in) the inner side (e.g., the medium portion) of the aerosol-generating article 2. The susceptor included inside the aerosol-generating article 2 may be implemented to be heated based on a magnetic field generated by the induction coil 181.

Referring to FIG. 2B, the heater 183 may be an external heating-type heater.

According to one embodiment, the external heating-type heater may be elongated upwardly around the space into which the aerosol-generating article 2 is inserted (i.e., the insertion space). For example, the external heating-type heater may be disposed so as to surround at least a portion of the insertion space. In an example, the external heating-type heater may include a tube shape (e.g., a cylindrical shape) with a cavity formed therein. The external heating-type heater may alternatively include a shape including a cavity formed therein and surrounding the cavity. In this case, the external heating-type heater may be supported by a polyimide film. The heater supported by this film may be referred to as a film heater. The external heating-type heater may be disposed so as to surround at least a portion of the insertion space. The external heating-type heater may heat the outer side of the aerosol-generating article 2 inserted into the cavity.

According to one embodiment, the external heating-type heater may include an electro-resistive heater and/or an induction heater, and a description of configurations identical to those shown in FIG. #a will be omitted. Meanwhile, in the case of an induction heater, the aerosol-generating device 1 may include an external heating-type heater implemented as a tubular susceptor and may include an induction coil 181 surrounding at least a portion of the external heating-type heater (e.g., disposed outside the heater so as to correspond to the length of at least a portion of the heater). In addition, the induction coil 181 may include a fan coil. Meanwhile, if the external heating-type heater is an electro-resistive heater, heat may be generated through current flow through the tubular electro-resistive heater (e.g., the film heater), and thus a separate induction coil 181 may be omitted. Meanwhile, a thermally insulating material may be disposed outside the external heating-type heater. Accordingly, the amount of heat emitted from the heater 183 in the radially outward direction and released outside the housing 10 may be reduced.

According to one embodiment, the heater 183 may be a multi-heater, and the first heater and the second heater may be disposed side by side in the longitudinal direction so as to surround at least a portion of the insertion space. The first heater and the second heater may operate as an electro-resistive heater and/or an induction heater, and may be heated sequentially or simultaneously. Meanwhile, if the heater 183 is an induction heater, the aerosol-generating device 1 may include a first induction coil and a second induction coil. The first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 183 in the longitudinal direction, respectively.

Unlike the configuration shown in FIG. 2A or FIG. 2B, both the heater 182 in FIG. 2A and the heater 183 in FIG. 2B may be included in the aerosol-generating device 1. In this case, the heater 182 may heat the inner side of the aerosol-generating article 2, and the heater 183 may heat the outer side of the aerosol-generating article 2.

According to one embodiment, the aerosol-generating device 1 may be provided with an airflow channel through which air flows. For example, the housing 10 may include a structure (e.g., a hole) through which outside air may be introduced into the housing 10. The air introduced into the housing 10 may be introduced into the aerosol-generating article 2 through the lower end (i.e., upstream side) of the aerosol-generating article 2. An aerosol generated based on heating of the aerosol-generating article 2 may be inhaled into the user's oral cavity together with the introduced air through the upper end (i.e., downstream side) of the aerosol-generating article 2.

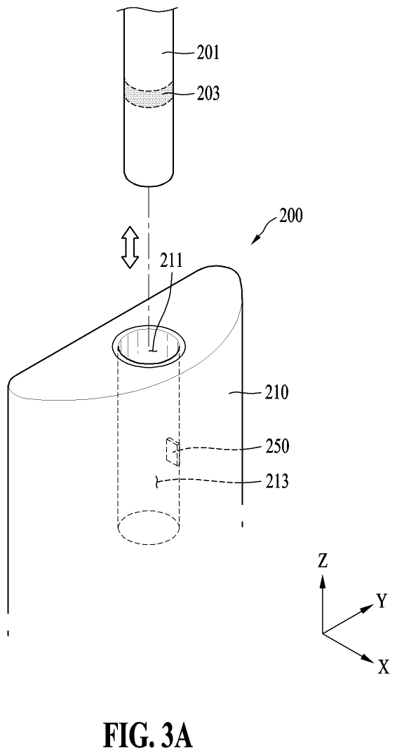

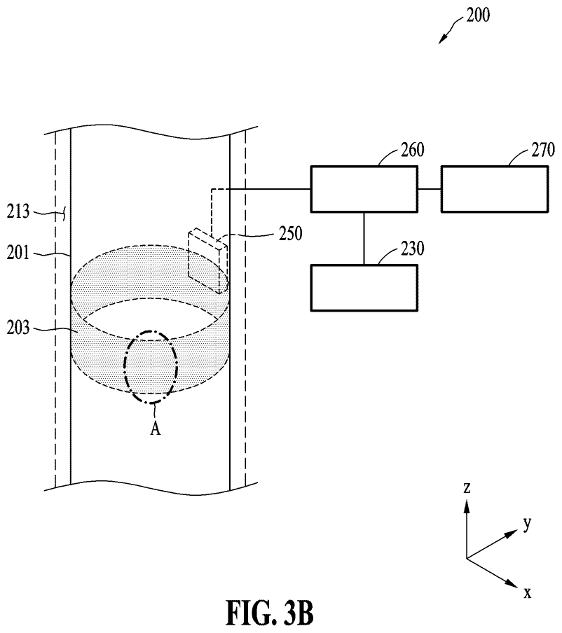

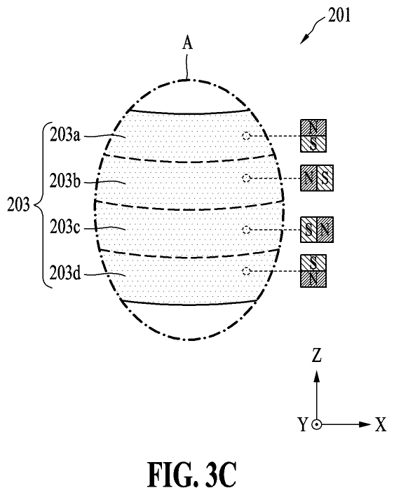

FIG. 3A is a schematic view of an aerosol-generating device 200 according to an embodiment. FIG. 3B is a schematic view of the aerosol-generating device 200 and an aerosol-generating article 201, according to an embodiment. FIG. 3C is a diagram of region A of the aerosol-generating article 201 illustrated in FIG. 3B.

Referring to FIGS. 3A, 3B and 3C, the aerosol-generating device 200 (e.g., the aerosol-generating device 1 of FIGS. 1, 2A, and 2B) may include a housing 210 and a magnetic sensor 250 (e.g., the sensor unit 13 of FIG. 1).

Hereinafter, the description provided above is not repeated, and it is obvious that some components and structures of the aerosol-generating device 200 may be replaced, added, or omitted within a scope in which those skilled in the art may easily understand with reference to the drawings and descriptions below. In addition, one or more components or features of the embodiments described above may be combined in the aerosol-generating device 200 unless it is technically and clearly infeasible.

In one embodiment, the housing 210 may form an exterior of the aerosol-generating device 200. Alternatively, the housing 210 may accommodate other components of the aerosol-generating device 200. The housing 210 may be a body or main body of the aerosol-generating device 200.

In one embodiment, the housing 210 may include an inlet 211. The inlet 211 may be an opening or a hole through which the aerosol-generating article 201 (e.g., the aerosol-generating article 2 of FIGS. 2A and 2B) is inserted. The inlet 211 may be formed to be open on one surface (e.g., an upper surface or a surface in a +Z direction) of the housing 210.

Hereinafter, an object inserted to the aerosol-generating device 200 according to various embodiments of the present disclosure is described as a stick-shaped aerosol-generating article 201, but in the actual implementation of the aerosol-generating device 200 is not limited thereto, and the aerosol-generating article 201 may be replaced with various shapes and structures such as a cartridge or a capsule.

In one embodiment, the housing 210 may include a cavity 213. The aerosol-generating article 201 may be inserted into the cavity 213. The cavity 213 may be an elongated cavity, a bonding region, an insertion region, or a heating region that accommodates the aerosol-generating article 201.

In one embodiment, the cavity 213 may have a shape corresponding to at least a portion of the aerosol-generating article 201. For example, the cavity 213 may have a cylindrical shape corresponding to the stick-shaped aerosol-generating article 201.

In one embodiment, the cavity 213 may be connected to the inlet 211. The cavity 213 may have a shape extending in one direction (e.g.,-Z direction) from the inlet 211. The aerosol-generating article 201 may be inserted longitudinally (e.g., in a Z-axis direction) through the inlet 211 into the cavity 213.

In one embodiment, the magnetic sensor 250 may be disposed in the cavity 213. The magnetic sensor 250 may detect magnetic information about the aerosol-generating article 201. Alternatively, the magnetic sensor 250 may detect whether the aerosol-generating article 201 is inserted into the cavity 213.

In one embodiment, the aerosol-generating article 201 may include magnetic printing 203. The magnetic printing 203 may be provided on at least a portion of an outer circumferential surface of the aerosol-generating article 201.

In one embodiment, magnetic information may be recorded on the magnetic printing 203. When the aerosol-generating article 201 is inserted into the cavity 213, the magnetic printing 203 may electromagnetically interact with the magnetic sensor 250. The magnetic sensor 250 may electromagnetically interact with the magnetic printing 203 to recognize the magnetic information recorded on the magnetic printing 203.

In one embodiment, the magnetic printing 203 may be magnetized in a predetermined direction. The magnetic sensor 250 may detect the magnetization direction of the magnetic printing 203 and recognize the magnetic information recorded on the magnetic printing 203.

In one embodiment, the magnetic printing 203 may include a plurality of magnetized regions 203a, 203b, 203c, and 203d. Each of the plurality of magnetized regions 203a, 203b, 203c, and 203d may be magnetized in a predetermined direction.

For example, as illustrated in FIG. 3C, each of the plurality of magnetized regions 203a, 203b, 203c, and 203d may be formed of a metallic material, and the metallic material may be magnetized such that the N pole faces one of a first direction (e.g., upper side or +Z direction), a second direction (e.g., left side or −X direction), a third direction (e.g., right side or +X direction), and a fourth direction (e.g., lower side or −Z direction).

In one embodiment, the plurality of magnetized regions 203a, 203b, 203c, and 203d may be magnetized in different directions, as illustrated in FIG. 3C. However, FIG. 3C is only an example, and at least some of the plurality of magnetized regions 203a, 203b, 203c, and 203d may be magnetized in the same direction.

In one embodiment of the present disclosure, the magnetic printing 203 may include magnetic information on the aerosol-generating article 201 as the plurality of magnetized regions 203a, 203b, 203c, and 203d is magnetized in various directions.

In addition, although FIG. 3C illustrates four magnetized regions 203a, 203b, 203c, and 203d, this is only an example, and the plurality of magnetized regions 203a, 203b, 203c, and 203d may be a single region or two or more regions. In addition, as illustrated in FIG. 3C, the plurality of magnetized regions 203a, 203b, 203c, and 203d may be arranged in a vertical direction, or at least some of the plurality of magnetized regions 203a, 203b, 203c, and 203d may be adjacent to one another in a left-right direction or may be arranged in a predetermined pattern or shape.

In one embodiment, the magnetization directions, arrangement, pattern, and/or shape of the plurality of magnetized regions 203a, 203b, 203c, and 203d of the magnetic printing 203 may be determined based on information on the aerosol-generating article 201 (e.g., the type of the aerosol-generating article 201, the authenticity of the aerosol-generating article 201, the type and/or content ratio of the contained materials of the aerosol-generating article 201, etc.). The magnetic sensor 250 may recognize magnetic information about the aerosol-generating article 201 from the magnetic printing 203.

In one embodiment, the magnetic sensor 250 may include a magnetoresistive (MR) sensor in which resistance changes according to a change in a magnetic field inside the cavity 213. The magnetic sensor 250 including the MR sensor may be advantageous for measuring the strength and direction of the magnetic field due to the magnetic printing 203.

In one embodiment, the magnetic sensor 250 may include a three-axis sensor that detects magnetic field changes with respect to three mutually orthogonal axes inside the cavity 213. The magnetic sensor 250 including the three-axis sensor may more accurately and precisely recognize the direction in which each of the plurality of magnetized regions 203a, 203b, 203c, and 203d is magnetized.

In one embodiment, at least one processor 260 (e.g., the controller 12 of FIGS. 1, 2A, and 2B) may receive a detection result from the magnetic sensor 250. A memory 270 (e.g., the memory 17 of FIG. 1) may be operatively connected to the at least one processor 260 and may store executable instructions. The at least one processor 260 may control the driving of the aerosol-generating device 200 by executing the instructions stored in the memory 270.

In one embodiment, the at least one processor 260 may receive a detection result from the magnetic sensor 250 and execute an instruction related to the magnetic sensor 250 among the instructions stored in the memory 270 to recognize the magnetic information about the aerosol-generating article 201 based on the detection result of the magnetic sensor 250.

In one embodiment, the memory 270 of the aerosol-generating device 200 may have information on an appropriate temperature profile and driving based on various types of information such as the type of the aerosol-generating article 201, the type of contained material, the content ratio of the material, the content of the material, and the degree of over-humidification.

In one embodiment, a heater 230 (e.g., the heater 18 or 24 of FIG. 1, the heater 182 of FIG. 2A, or the heater 183 of FIG. 2B) may heat the aerosol-generating article 201 inserted into the cavity 213. The heater 230 may heat the aerosol-generating article 201 to generate an aerosol.

In one embodiment, the driving of the heater 230 may be controlled by the at least one processor 260. The at least one processor 260 may control the driving of the heater 230 based on the magnetic information detected by the magnetic sensor 250.

For example, the at least one processor 260 may execute an instruction for information (e.g., driving time, driving cycle, driving intensity, etc.) about the driving of the heater 230 from the memory 270 based on identified magnetic information to perform driving customized to the aerosol-generating article 201.

In one embodiment of the present disclosure, the aerosol-generating device 200 may provide customized driving for the aerosol-generating article 201 through the magnetic sensor 250. The aerosol-generating device 200 may provide a user with an improved user experience for various aerosol-generating articles (e.g., 201).

In one embodiment of the present disclosure, the aerosol-generating device 200 may recognize identification information for the aerosol-generating article 201 identified through the magnetic sensor 250 and automatically customize and control the driving of the aerosol-generating device 200 based on the identification information, even without the user inputting information about the aerosol-generating article 201 or directly controlling the driving of the aerosol-generating device 200.

In one embodiment, the magnetic printing 203 may be heated by the heater 230 when the heater 230 is driven, weakening or erasing the recorded magnetic information. Alternatively, the magnetic printing 203 may provide the magnetic sensor 250 with information about whether the aerosol-generating article 201 is used.

For example, after the magnetic printing 203 is heated by the heater 230, the strength of a magnetic field formed by the magnetic printing 203 electromagnetically interacting with the magnetic sensor 250 may be weakened.

In one embodiment, the magnetic sensor 250 may determine whether the aerosol-generating article 201 is used the second time according to whether the strength of the magnetic field for the magnetic information recorded on the magnetic printing 203 is less than or equal to a reference value.

In one embodiment of the present disclosure, the aerosol-generating device 200 may prevent the aerosol-generating article 201 from being used the second time or reused by weakening or erasing a record of the magnetic information of the magnetic printing 203 through the heater 230.

In one embodiment of the present disclosure, when the aerosol-generating device 200 detects a weak magnetic field strength for the magnetic information through the magnetic sensor 250, the aerosol-generating device 200 may prevent the user from reusing the aerosol-generating article 201 by restricting the driving of the heater 230.

For example, when the aerosol-generating article 201 is used the second time or reused, an aerosol having a different composition than the initial use may be generated, harmful substances may be generated, and the user's smoking experience may be degraded.

In one embodiment of the present disclosure, the aerosol-generating device 200 may weaken or erase the record of the magnetic information of the magnetic printing 203 when the aerosol-generating article 201 is used for the first time, and the magnetic sensor 250 may prevent the aerosol-generating article 201 from being used the second time or reused by detecting the strength of the magnetic field for the magnetic information.

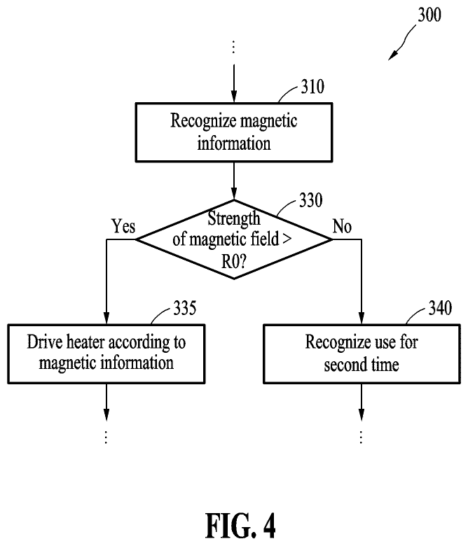

FIG. 4 is a flowchart of a method 300 of controlling an aerosol-generating device, according to an embodiment.

Referring to FIG. 4, the method 300 of controlling the aerosol-generating device according to one embodiment may include at least some of operation 310 of recognizing magnetic information, operation 330 of determining the strength of a magnetic field, operation 335 of driving a heater, and operation 340 of recognizing use for the second time.

Hereinafter, the description provided above is not repeated, and it is obvious that some components and structures of the aerosol-generating device and the method 300 of controlling the aerosol-generating device may be replaced, added, or omitted within a scope in which those skilled in the art may easily understand with reference to the drawings and descriptions below. In addition, one or more components or features of the embodiments described above may be combined in the aerosol-generating device and the method 300 of controlling the aerosol-generating device unless it is technically and clearly infeasible.

In one embodiment, each operation of the method 300 of controlling the aerosol-generating device may be performed by at least one processor executing instructions stored in a memory. Alternatively, the method 300 of controlling the aerosol-generating device may be performed by a main processor or may be performed together by the main processor, an auxiliary processor, or other components.

The method 300 of controlling the aerosol-generating device according to one embodiment may be the method 300 targeting the aerosol-generating device described above (e.g., the aerosol-generating device 1 of FIGS. 1, 2A, and 2B or the aerosol-generating device 200 of FIGS. 3A and 3B), but embodiments are not limited thereto, and the method 300 may be the method 300 of controlling an aerosol-generating device of another type, shape, structure, and configuration.

In one embodiment, operation 310 of recognizing magnetic information may be an operation in which a magnetic sensor may recognize magnetic information from an article inserted into the aerosol-generating device. The magnetic sensor may electromagnetically interact with magnetic printing of an inserted aerosol-generating article to obtain information about the aerosol-generating article.

However, although FIG. 4 illustrates that operation 310 of recognizing magnetic information is performed before operation 330 of determining the strength of a magnetic field, this is only an example of the method 300. For example, operation 310 of recognizing magnetic information may be performed after operation 330 of determining the strength of a magnetic field, and specifically, may be performed before operation 335 of driving a heater.

In one embodiment, operation 330 of determining the strength of a magnetic field may determine whether the strength of a magnetic field for magnetic information recognized by the magnetic sensor is less than or equal to a reference value R0. The reference value R0 that is a determination criterion may be a value that is equal to or less than half of magnetic field strength for an unused aerosol-generating article that is recognized on average or in general.

For example, the average (or median) magnetic field strength recognized by the magnetic sensor through magnetic printing of the unused aerosol-generating article may be R amperes per meter (A/m), and the reference value R0, which is the determination criterion, may be 0.5 R(A/m). In a state in which an aerosol-generating article is inserted, when the magnetic field strength recognized by the magnetic sensor is 0.5 R(A/m) or less, the aerosol-generating device may determine that the inserted aerosol-generating article is used the second time.

In one embodiment, the method 300 may perform operation 335 of driving the heater when the strength of the magnetic field for the magnetic information recognized by the magnetic sensor is greater than the reference value R0. Operation 335 of driving the heater may drive the heater appropriately for the aerosol-generating article according to the magnetic information.

In one embodiment, the method 300 may perform operation 340 of recognizing use for the second time when the strength of the magnetic field for the magnetic information recognized by the magnetic sensor is less than or equal to the reference value R0. Operation 340 of recognizing use for the second time may control driving conditions such as the driving time, driving cycle, and driving strength of the heater to suit the aerosol-generating article according to the magnetic information.

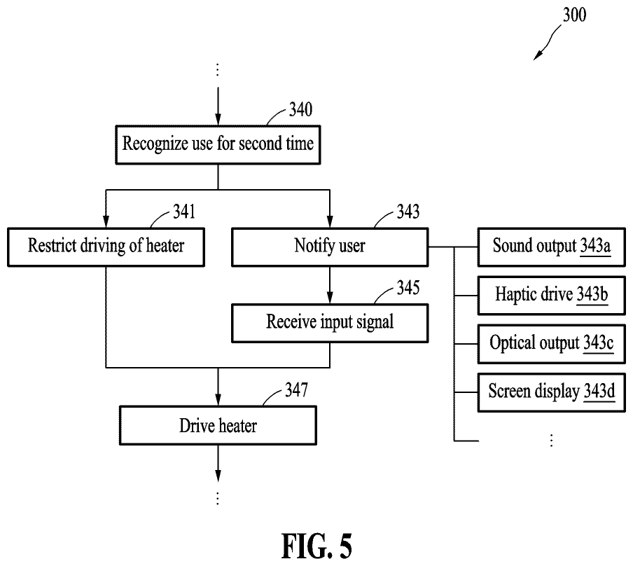

FIG. 5 is a flowchart of the method 300 of controlling an aerosol-generating device according to an embodiment.

Referring to FIG. 5, the method 300 of controlling the aerosol-generating device according to one embodiment may include at least some of operation 341 of restricting driving of a heater, operation 343 of notifying a user, operation 345 of receiving an input signal, and operation 347 of driving the heater.

Hereinafter, the description provided above is not repeated, and it is obvious that some components and structures of the aerosol-generating device and the method 300 of controlling the aerosol-generating device may be replaced, added, or omitted within a scope in which those skilled in the art may easily understand with reference to the drawings and descriptions below. In addition, one or more components or features of the embodiments described above may be combined in the aerosol-generating device and the method 300 of controlling the aerosol-generating device unless it is technically and clearly infeasible.

FIG. 5 is a flowchart illustrating examples of operations that may be performed by the method 300 after operation 340 of recognizing that an aerosol-generating article is used the second time.

In one embodiment, the method 300 may perform at least one of operation 341 of restricting the driving of the heater and operation 343 of notifying the user, or both, after operation 340 of recognizing use for the second time.

In one embodiment, operation 341 of restricting the driving of the heater may block power supplied to the heater when it is detected that the aerosol-generating article is used the second time. Since the aerosol-generating article being used the second time may generate an aerosol having a different composition than the initial use, may generate hazardous substances, and may degrade the user's smoking experience. Therefore, the aerosol-generating article may be prevented from being used the second time by restricting the driving of the heater.

In one embodiment, operation 343 of notifying the user may output information about second-time use to the user through an output unit (e.g., the output unit 14 of FIG. 1) that displays sound information, vibration information, optical information, or screen information. For example, operation 343 of notifying the user may include at least some of a plurality of output schemes (e.g., a sound output operation 343a, a haptic drive operation 343b, an optical output operation 343c, and a screen display operation 343d).

In one embodiment, the sound output operation 343a may transmit a notification sound or instruction guide to the user. In one embodiment, the haptic drive operation 343b may transmit a vibration signal to the user. In one embodiment, the optical output operation 343c may output a flashing light signal or a predetermined colored light to the user. In one embodiment, the screen display operation 343d may output second-time use guidance to the user through a display.

In one embodiment, operation 345 of receiving an input signal may receive an input signal from another component (e.g., an insertion detection sensor), a user, or an external device via an input unit (e.g., the input unit 15 of FIG. 1). For example, an input signal may be a heater driving resume signal or a forced driving signal.

In one embodiment, when the input signal is received, the method 300 may terminate operation 341 of restricting the driving of the heater and proceed to operation 347 of driving the heater. Operation 347 of driving the heater may drive the heater.

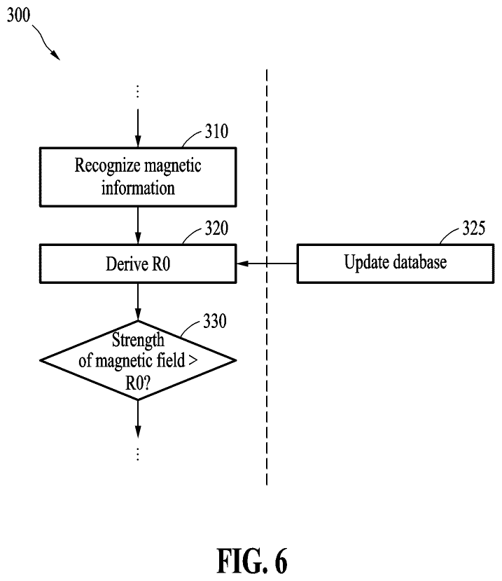

FIG. 6 is a flowchart of the method 300 of controlling the aerosol-generating device according to an embodiment.

Referring to FIG. 6, the method 300 of controlling the aerosol-generating device according to one embodiment may include at least some of operation 320 of deriving a reference value and operation 325 of updating a database.

Hereinafter, the description provided above is not repeated, and it is obvious that some components and structures of the aerosol-generating device and the method 300 of controlling the aerosol-generating device may be replaced, added, or omitted within a scope in which those skilled in the art may easily understand with reference to the drawings and descriptions below. In addition, one or more components or features of the embodiments described above may be combined in the aerosol-generating device and the method 300 of controlling the aerosol-generating device unless it is technically and clearly infeasible.

FIG. 6 is a flowchart illustrating examples of operations that may be performed by the method 300 prior to operation 330 of determining the strength of the magnetic field of the aerosol-generating article.

In one embodiment, operation 320 of deriving the reference value may retrieve an appropriate reference value R0 from a memory based on magnetic information. The memory may store a reference value for the strength of the magnetic field that is a basis for determining second-time use. Operation 320 of deriving the reference value may retrieve an appropriate reference value that is the basis for determining whether the magnetic field is used the second time from among a plurality of reference values based on the magnetic information recognized by a magnetic sensor.

For example, the reference value R0 may need to be adjusted based on various factors, such as a region of use of the aerosol-generating device, an environment in which the aerosol-generating device is used, a production environment of the aerosol-generating article, and a distribution route of the aerosol-generating article. For example, an aerosol-generating article distributed in a region with high average temperatures or produced or distributed during periods of high average temperatures may exhibit somewhat weakened magnetic printing. The method 300 may consider the fact that the magnetic printing may be weakened and derive the reference value R0 by adjusting the reference value R0 based on the magnetic information.

In one embodiment, operation 325 of updating a database may update a database of reference values stored in the memory based on information input through a communication unit (e.g., the communication unit 16 of FIG. 1). For example, operation 325 of updating a database may adjust the numerical value of a reference value, add a new reference value, or delete duplicate or unnecessary reference values among a plurality of reference values.

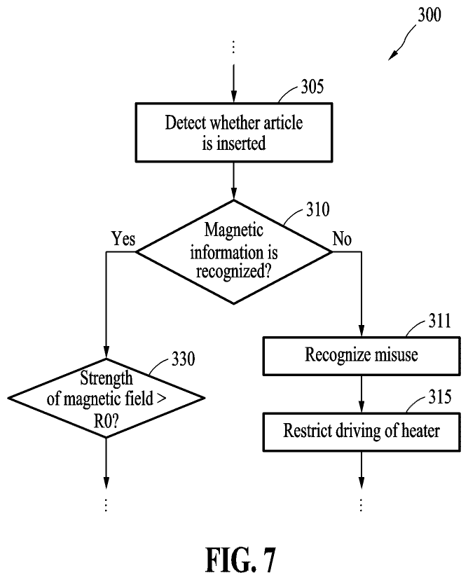

FIG. 7 is a flowchart of the method 300 of the aerosol-generating device according to an embodiment.

Referring to FIG. 7, the method 300 of the aerosol-generating device according to one embodiment may include at least some of operation 305 of detecting whether an article is inserted, operation 325 of recognizing a misuse, and operation 315 of restricting driving of a heater.

Hereinafter, the description provided above is not repeated, and it is obvious that some components and structures of the aerosol-generating device and the method 300 of controlling the aerosol-generating device may be replaced, added, or omitted within a scope in which those skilled in the art may easily understand with reference to the drawings and descriptions below. In addition, one or more components or features of the embodiments described above may be combined in the aerosol-generating device and the method 300 of controlling the aerosol-generating device unless it is technically and clearly infeasible.

FIG. 7 is a flowchart illustrating examples of operations that may be performed by the method 300 prior to operation 330 of determining the strength of the magnetic field of the aerosol-generating article.

In one embodiment, operation 305 of detecting whether an article is inserted may detect whether an aerosol-generating article or another article is inserted into a cavity from an insertion detection sensor (e.g., the sensor unit 13 of FIG. 1). Operation 310 of recognizing magnetic information may determine whether magnetic information is recognized when the insertion of an article is detected.

In one embodiment, when no magnetic information is detected by a magnetic sensor in operation 310 of recognizing magnetic information, the method 300 may recognize that an article is misused. Operation 311 of recognizing a misuse may recognize that an article inserted into a cavity is misused or used repeatedly. For example, when the inserted article is a counterfeit, a damaged article, or is misused, magnetic printing may not be present or may be damaged.

In one embodiment, the method 300 may perform operation 315 of restricting the driving of a heater after operation 311 of recognizing a misuse, thereby blocking power transmitted to the heater or temporarily restricting the driving of the heater. Although not shown in the drawing, the method 300 may perform operation 311 of recognizing a misuse and then perform an operation notifying a user of the misuse.

However, the above description is only an example of the aerosol-generating device 100 according to one embodiment of the present disclosure and does not necessarily indicate that the aerosol-generating device 100 includes any one of the components described above. In addition, it is obvious that the description of the components described above may be modified and implemented in a substantially identical or similar or equivalent range that may be easily changed by those skilled in the art and that these components are also included in the aerosol-generating device 100 according to one embodiment of the present disclosure.

According to one embodiment, an aerosol-generating device may include a cavity, a heater configured to heat an article inserted into the cavity, a magnetic sensor disposed in the cavity, at least one processor configured to receive a detection result from the magnetic sensor and control driving of the heater, and a memory operatively connected to the at least one processor and storing executable instructions. In one embodiment, the at least one processor may be configured to, by executing the instructions stored in the memory, control the driving of the heater according to magnetic information detected by the magnetic sensor and determine whether the article is used the second time according to whether strength of a magnetic field for the magnetic information detected by the magnetic sensor is less than or equal to a reference value.

In one embodiment, the magnetic sensor may include an MR sensor in which resistance changes according to a change in a magnetic field inside the cavity.

In one embodiment, the magnetic sensor may include a three-axis sensor configured to detect a magnetic field change with respect to three mutually orthogonal axes inside the cavity.

In one embodiment, the at least one processor may be configured to, by executing the instructions stored in the memory, block power supplied to the heater when it is recognized that the article is used the second time.

In one embodiment, the aerosol-generating device may further include an output unit configured to display sound information, vibration information, optical information, or screen information. In one embodiment, the at least one processor may be configured to, by executing the instructions stored in the memory, output information about the article being used the second time through the output unit when it is recognized that the article is used the second time.

In one embodiment, the aerosol-generating device may further include an input unit configured to receive input information. In one embodiment, the at least one processor may be configured to, by executing the instructions stored in the memory, drive the heater when an input signal is received from the input unit after the information about the article being used the second time is output through the output unit.

In one embodiment, the memory may be configured to store a plurality of reference values for magnetic field strength that is a basis for determining use for the second time, and the at least one processor may be configured to, based on magnetic information recognized by the magnetic sensor, retrieve one reference value from among the plurality of reference values.

In one embodiment, the aerosol-generating device may further include a communication unit configured to establish a communication link with an outside of the aerosol-generating device. In one embodiment, the at least one processor may be configured to update a database for the reference value stored in the memory according to information that is input through the communication unit.

In one embodiment, the aerosol-generating device may further include an insertion detection sensor configured to detect whether an article is inserted into the cavity. In one embodiment, the at least one processor may be configured to, by executing the instructions stored in the memory, recognize that the article is misused when the insertion detection sensor detects that the article is inserted into the cavity but the magnetic sensor has no detected magnetic information.

In one embodiment, the at least one processor may be configured to, by executing the instructions stored in the memory, restrict the driving of the heater when it is recognized that the article is misused.

In one embodiment, an aerosol-generating system may include an aerosol-generating article including magnetic printing on which magnetic information is recorded, a cavity configured to accommodate the aerosol-generating article, a heater disposed in the cavity, and a magnetic sensor configured to recognize the magnetic information of the magnetic printing. In one embodiment, when the heater is driven, the magnetic printing is heated by the heater, so a record of the magnetic information may be weakened or erased.

In one embodiment, the aerosol-generating system may further include at least one processor configured to receive a detection result from the magnetic sensor and control driving of the heater and a memory operatively connected to the at least one processor and storing executable instructions. In one embodiment, the at least one processor may be configured to, by executing the instructions stored in the memory, control the driving of the heater according to magnetic information detected by the magnetic sensor from the aerosol-generating article and determine whether the aerosol-generating article is used the second time according to whether strength of a magnetic field for the magnetic information detected by the magnetic sensor is less than or equal to a reference value.

In one embodiment, the magnetic printing may include a plurality of magnetized regions, and each of the plurality of magnetized regions may be magnetized in a predetermined direction.

In one embodiment, the magnetic sensor may be configured to recognize the magnetic information based on a direction in which each of the plurality of magnetized regions is magnetized.

In one embodiment, a method of controlling an aerosol-generating device may include recognizing, by a magnetic sensor, magnetic information from an article that is inserted into the aerosol-generating device and determining whether strength of a magnetic field for the magnetic information recognized by the magnetic sensor is less than or equal to a reference value. In one embodiment, when the strength of the magnetic field for the magnetic information recognized by the magnetic sensor is greater than the reference value, the method may drive a heater configured to heat the article according to the magnetic information, and when the strength of the magnetic field for the magnetic information recognized by the magnetic sensor is less than or equal to the reference value, the method may recognize that the article is used the second time.

Certain embodiments or other embodiments of the disclosure described above are not mutually exclusive or distinct from each other. Some embodiments of the disclosure described above or other embodiments may be used jointly or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The above detailed description should not be construed in all aspects as limiting and should be considered illustrative. The scope of the present disclosure should be determined by rational interpretation of the appended claims, and all variations within the scope of equivalents of the present disclosure are included in the scope of the present disclosure.

What is claimed is:

1. An aerosol-generating device comprising:
a cavity;
a heater configured to heat an article inserted into the cavity;
a magnetic sensor disposed in the cavity;
at least one processor configured to receive a detection result from the magnetic sensor and control driving of the heater; and
a memory operatively connected to the at least one processor and storing executable instructions,
wherein the at least one processor is configured to, by executing the instructions stored in the memory:
control the driving of the heater according to magnetic information detected by the magnetic sensor; and
determine whether the article is used a second time according to whether strength of a magnetic field for the magnetic information detected by the magnetic sensor is less than or equal to a reference value.

2. The aerosol-generating device of claim 1, wherein the magnetic sensor comprises a magnetoresistive (MR) sensor in which resistance changes according to a change in a magnetic field inside the cavity.

3. The aerosol-generating device of claim 1, wherein the magnetic sensor comprises a three-axis sensor configured to detect a magnetic field change with respect to three mutually orthogonal axes inside the cavity.

4. The aerosol-generating device of claim 1, wherein the at least one processor is configured to, by executing the instructions stored in the memory, block power supplied to the heater when it is recognized that the article is used the second time.

5. The aerosol-generating device of claim 1, further comprising:
an output unit configured to display sound information, vibration information, optical information, or screen information,
wherein the at least one processor is configured to, by executing the instructions stored in the memory, output information about the article being used the second time through the output unit when it is recognized that the article is used the second time.

6. The aerosol-generating device of claim 5, further comprising:
an input unit configured to receive input information,
wherein the at least one processor is configured to, by executing the instructions stored in the memory, drive the heater when an input signal is received from the input unit after the information about the article being used the second time is output through the output unit.

7. The aerosol-generating device of claim 1, wherein
the memory is configured to store a plurality of reference values for magnetic field strength that is a basis for determining use for the second time, and
the at least one processor is configured to, based on magnetic information recognized by the magnetic sensor, retrieve one reference value from among the plurality of reference values.

8. The aerosol-generating device of claim 1, further comprising:
a communication unit configured to establish a communication link with an outside of the aerosol-generating device,
wherein the at least one processor is configured to update a database for the reference value stored in the memory according to information that is input through the communication unit.

9. The aerosol-generating device of claim 1, further comprising:
an insertion detection sensor configured to detect whether an article is inserted into the cavity,
wherein the at least one processor is configured to, by executing the instructions stored in the memory, recognize that the article is misused when the insertion detection sensor detects that the article is inserted into the cavity but the magnetic sensor has no detected magnetic information.

10. The aerosol-generating device of claim 9, wherein the at least one processor is configured to, by executing the instructions stored in the memory, restrict the driving of the heater when it is recognized that the article is misused.

11. An aerosol-generating system comprising:
an aerosol-generating article comprising magnetic printing on which magnetic information is recorded;
a cavity configured to accommodate the aerosol-generating article;
a heater disposed in the cavity; and
a magnetic sensor configured to recognize the magnetic information of the magnetic printing,
wherein, when the heater is driven, the magnetic printing is heated by the heater, so a record of the magnetic information is weakened or erased.

12. The aerosol-generating system of claim 11, further comprising:
at least one processor configured to receive a detection result from the magnetic sensor and control driving of the heater; and
a memory operatively connected to the at least one processor and storing executable instructions,
wherein the at least one processor is configured to, by executing the instructions stored in the memory:
control the driving of the heater according to magnetic information detected by the magnetic sensor from the aerosol-generating article; and
determine whether the aerosol-generating article is used a second time according to whether strength of a magnetic field for the magnetic information detected by the magnetic sensor is less than or equal to a reference value.

13. The aerosol-generating system of claim 11, wherein the magnetic printing comprises a plurality of magnetized regions, and each of the plurality of magnetized regions is magnetized in a predetermined direction.

14. The aerosol-generating system of claim 13, wherein the magnetic sensor is configured to recognize the magnetic information based on a direction in which each of the plurality of magnetized regions is magnetized.

15. A method of controlling an aerosol-generating device, the method comprising:
recognizing, by a magnetic sensor, magnetic information from an article that is inserted into the aerosol-generating device; and
determining whether strength of a magnetic field for the magnetic information recognized by the magnetic sensor is less than or equal to a reference value,
wherein when the strength of the magnetic field for the magnetic information recognized by the magnetic sensor is greater than the reference value, the method drives a heater configured to heat the article according to the magnetic information, and
wherein when the strength of the magnetic field for the magnetic information recognized by the magnetic sensor is less than or equal to the reference value, the method recognizes that the article is used a second time.
